(19) United States
(12) Patent Application Publication
(10) Pub. No.: US 2026/0130223 A1
(43) Pub. Date: May 7, 2026

(54) SEMICONDUCTOR APPARATUS

(71) Applicant: Mitsubishi Electric Corporation, Tokyo (JP)

(72) Inventors: Norikazu SAKAI, Fukuoka (JP); Kazuhiro NISHIMURA, Fukuoka (JP); Minoru EGUSA, Tokyo (JP); Fumio WADA, Tokyo (JP); Hiroyuki MASUMOTO, Tokyo (JP)

(73) Assignee: Mitsubishi Electric Corporation, Tokyo (JP)

(21) Appl. No.: 19/211,742

(22) Filed: May 19, 2025

(30) Foreign Application Priority Data
Nov. 6, 2024 (JP) 2024-194145

(51) Int. Cl. H01L 23/00; H01L 23/13; H01L 23/31

(52) U.S. Cl. CPC H10W 42/121; H10W 70/68; H10W 74/111

(57) ABSTRACT

A semiconductor apparatus includes: an insulating layer; a first metal plate provided on an upper face of the insulating layer; a second metal plate provided on a lower face of the insulating layer; a semiconductor device joined to the first metal plate; and an insulating mold resin covering the insulating layer, the first metal plate, a side face of the second metal plate, and the semiconductor device, wherein a recessed groove is provided on an entire periphery of a lower face of the second metal plate, and an inside of the recessed groove is filled with the insulating mold resin.

### BACKGROUND OF THE INVENTION

### Field

The present disclosure relates to a semiconductor apparatus.

### Background

Patent Literature 1 discloses providing, in a semiconductor apparatus in which a semiconductor device is mounted on an insulating substrate and sealed with an insulating mold resin, a recessed groove on a lower face of a lower electrode of the insulating substrate to inhibit internal peeling.

### CITATION LIST

### Patent Literature

Patent Literature 1: WO 2016/098431

### SUMMARY

### Technical Problem

In order to further improve heat dissipation and extend life, it is necessary to firmly seal the insulating substrate and the semiconductor device with the insulating mold resin without peeling. In Patent Literature 1, the recessed groove is provided at a corner of the lower face of the lower electrode of the insulating substrate as a stress relief measure for the insulating substrate against thermal stress. However, providing the recessed groove only at the corner cannot sufficiently relieve the stress, and it is not possible to prevent the insulating mold resin from peeling off.

The present disclosure has been made to solve the above-mentioned problem, and an object thereof is to obtain a semiconductor apparatus that can prevent an insulating mold resin from peeling off.

### Solution to Problem

A semiconductor apparatus according to the present disclosure includes: an insulating layer; a first metal plate provided on an upper face of the insulating layer; a second metal plate provided on a lower face of the insulating layer; a semiconductor device joined to the first metal plate; and an insulating mold resin covering the insulating layer, the first metal plate, a side face of the second metal plate, and the semiconductor device, wherein a recessed groove is provided on an entire periphery of a lower face of the second metal plate, and an inside of the recessed groove is filled with the insulating mold resin.

### Advantageous Effects of Invention

In the semiconductor apparatus according to the present disclosure, the recessed groove is provided on the entire periphery of the lower face of the second metal plate. The inside of the recessed groove is filled with the insulating mold resin. Thus, it is possible to prevent peeling of the insulating mold resin.

### BRIEF DESCRIPTION OF DRAWINGS

FIG. 1 is a sectional view of a semiconductor apparatus according to a first embodiment.

FIG. 2 is a bottom view of the insulating substrate according to the first embodiment.

FIG. 3 is a sectional view taken along line I-II of FIG. 2.

FIG. 4 is a sectional view of a semiconductor apparatus according to Comparative Example 1.

FIG. 5 is an enlarged sectional view of a part of the semiconductor apparatus according to Comparative Example 1.

FIG. 6 is a sectional view illustrating a modification of the semiconductor apparatus according to the first embodiment.

FIG. 7 is an enlarged sectional view of a part of a semiconductor apparatus according to Comparative Example 2.

FIG. 8 is a bottom view of an insulating substrate of a semiconductor apparatus according to a second embodiment.

FIG. 9 is a sectional view taken along line I-II of FIG. 8.

FIG. 10 is a bottom view illustrating a modification of the insulating substrate according to the second embodiment.

FIG. 11 is a sectional view taken along line I-II of FIG. 10.

FIG. 12 is a sectional view of a semiconductor apparatus according to a third embodiment.

FIG. 13 is a bottom view of an insulating substrate according to the third embodiment.

FIG. 14 is a sectional view taken along line I-II of FIG. 13.

FIG. 15 is a sectional view of an insulating substrate of a semiconductor apparatus according to the fourth embodiment.

FIG. 16 is a sectional view of a semiconductor apparatus according to a fifth embodiment.

FIG. 17 is a bottom view of an insulating substrate of a semiconductor apparatus according to a sixth embodiment.

FIG. 18 is a bottom view of the semiconductor apparatus according to the sixth embodiment.

### DESCRIPTION OF EMBODIMENTS

Hereinbelow, detailed description will be made with reference to the drawings. Redundant description will be simplified or omitted as appropriate. Identical reference signs denote the same or equivalent parts throughout the drawings. In addition, the size relationships between the components in the drawings may differ from the actual relationships. Furthermore, the modes of the elements shown in the full specification are merely examples, and the present disclosure is not limited to the modes described in the specification. In particular, the combinations of the elements are not limited to the combinations in each embodiment, and the elements described in one embodiment can be applied to another embodiment.

### First Embodiment

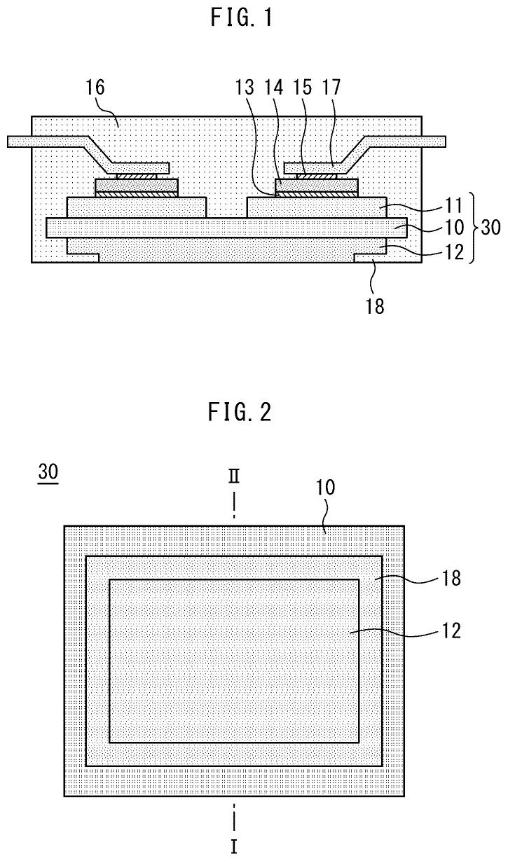

FIG. 1 is a sectional view of a semiconductor apparatus according to a first embodiment. The semiconductor apparatus is a transfer molded-power module. A first metal plate 11 is provided on an upper face of an insulating layer 10. A second metal plate 12 is provided on a lower face of the insulating layer 10. The insulating layer 10, the first metal plate 11, and the second metal plate 12 are collectively referred to as an insulating substrate 30.

The insulating layer 10 is a plate-like member having a rectangular shape in plan view. Here, the insulating layer 10 is made of ceramic. The material of ceramic is aluminum nitride, aluminum oxide, silicon nitride, alumina, or silicon carbide. Among these materials, aluminum nitride is preferable from the viewpoint of thermal conductivity. The thickness of the insulating layer 10 is preferably thin from the viewpoint of thermal conductivity. The thickness of the insulating layer 10 is selected in accordance with the size of a circuit board, the thermal conductivity of the material used, or the strength. The first metal plate 11 and the second metal plate 12 are made of, for example, copper. However, the first metal plate 11 and the second metal plate 12 may be made of aluminum or silver.

A semiconductor device 14 is joined to an upper face of the first metal plate 11 using a first joining material 13. The material of the first joining material 13 is, for example, solder. The first metal plate 11 and the semiconductor device 14 may be metal sintered.

The semiconductor device 14 is, for example, an insulated gate bipolar transistor (IGBT). However, the semiconductor device 14 may be a free wheeling diode (FWD) or a metal-oxide-semiconductor field-effect transistor (MOSFET).

A wiring member 17 is joined to an upper face of the semiconductor device 14 using a second joining material 15. The material of the second joining material 15 is, for example, solder. The wiring member 17 is a conductive member that mediates power supply from outside the apparatus to the semiconductor device 14 and input and output of electrical signals. The wiring member 17 is made of, for example, copper. However, the wiring member 17 may be made of metal other than copper.

An insulating mold resin 16 covers the insulating layer 10, the first metal plate 11, side faces of the second metal plate 12, the semiconductor device 14, and a part of the wiring member 17. The material of the insulating mold resin 16 is epoxy resin added with a filler.

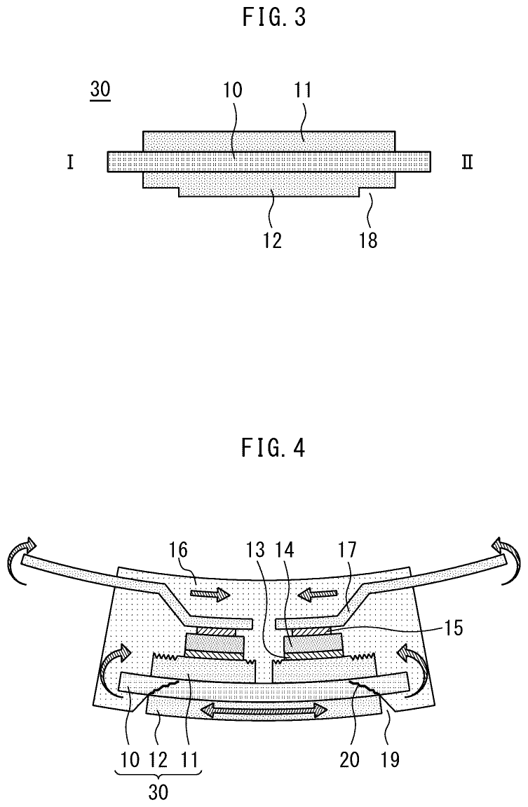

FIG. 2 is a bottom view of the insulating substrate according to the first embodiment. FIG. 3 is a sectional view taken along line I-II of FIG. 2. A recessed groove 18 is provided on the entire periphery of a lower face of the second metal plate 12.

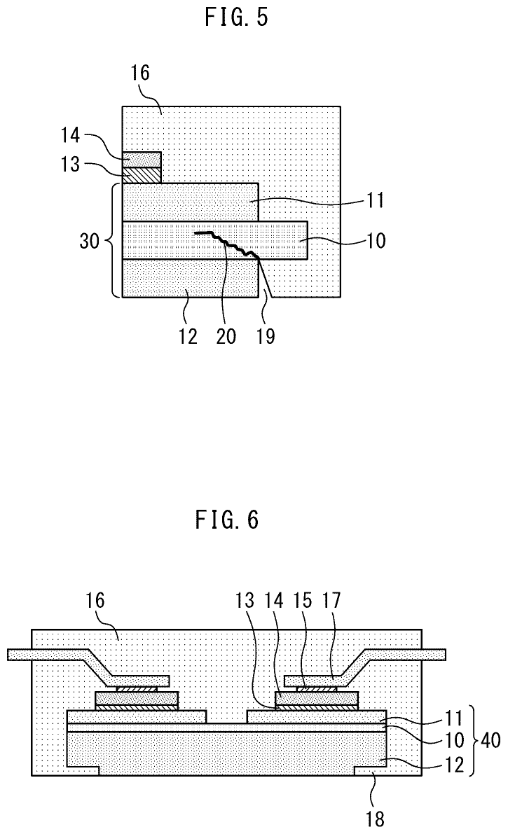

Next, the effects of the present embodiment will be described through a comparison with Comparative Example 1. FIG. 4 is a sectional view of a semiconductor apparatus according to Comparative Example 1. FIG. 5 is an enlarged sectional view of a part of the semiconductor apparatus according to Comparative Example 1. In Comparative Example 1, the recessed groove 18 is not formed in the second metal plate 12. Since the linear expansion coefficient of the insulating mold resin 16 differs from the linear expansion coefficient of the insulating substrate 30, when thermal expansion occurs due to a temperature change, the second metal plate 12 deforms, which causes peeling 19 at an interface between the insulating substrate 30 and the insulating mold resin 16. The peeling 19 also causes a crack 20 in the insulating layer 10.

On the other hand, in the present embodiment, since the recessed groove 18 is provided on the entire periphery of the lower face of the second metal plate 12, stress can be sufficiently relieved. In addition, the inside of the recessed groove 18 is filled with the insulating mold resin 16. This reinforces the joining between the insulating mold resin 16 and the insulating substrate 30. Thus, it is possible to prevent peeling of the insulating mold resin 16 caused by the difference in linear expansion coefficient between the insulating mold resin 16 and the insulating substrate 30. In addition, since the occurrence of a crack in the insulating layer 10 caused by the peeling can be prevented, the dielectric withstand voltage is also improved. Peeling at an interface between the first metal plate 11 or the semiconductor device 14 and the insulating mold resin 16 can also be prevented. As a result, it is possible to avoid a failure of the semiconductor apparatus in a temperature humidity bias test.

The depth of the recessed groove 18 is preferably one-third the thickness of the second metal plate 12 or more. This uniformly disperses the filler inside the insulating mold resin 16 that fills the recessed groove 18 and stabilizes the material properties of the insulating mold resin 16. In addition, since bending stress can be relieved, deformation of the second metal plate 12 can be inhibited.

The depth of the recessed groove 18 is preferably less than 51% of the thickness of the second metal plate 12. This makes it possible to inhibit the entry of the filler into the recessed groove 18, and the resin component of the insulating mold resin 16 enters the recessed groove 18 in large quantities, which improves the adhesion strength. Thus, it is possible to withstand deformation stress of the semiconductor apparatus and also withstand shrinkage stress that occurs during cooling in a molding process of the insulating mold resin 16. As a result, it is possible to prevent the insulating mold resin 16 from peeling off. Even after a heat cycle test is performed for 1000 hours at a test temperature of −40° C. to 125° C. and a 30-minute swing, no peeling of the insulating mold resin 16 occurs.

A bottom face of the recessed groove 18 has a flat shape. The flat shape of the recessed groove 18 cannot be formed by etching. Thus, the width of the recessed groove 18 is 0.5 mm or more. In addition, when the width of the recessed groove 18 is 0.45 mm or more, the effect of inhibiting peeling is achieved. It is preferable to perform laser irradiation on the flat portion of the bottom face of the recessed groove 18 in post-processing to roughen the bottom face by the laser. This further reinforces the joining between the bottom face of the recessed groove 18 and the insulating mold resin 16. Thus, it is possible to further inhibit peeling in a tensile direction and a shear direction caused by the difference in linear expansion between the insulating mold resin 16 and the insulating substrate 30. Here, the tensile direction is the right-left direction in FIG. 4, and the shear direction is the up-down direction in FIG. 4.

FIG. 6 is a sectional view illustrating a modification of the semiconductor apparatus according to the first embodiment. In the modification, a heat spreader 40 is used instead of the insulating substrate 30 of the first embodiment. In this case, the insulating layer 10 is not ceramic, but an insulating sheet made of epoxy resin added with a filler. The second metal plate 12 is a thick Cu block. The insulating layer 10, the first metal plate 11, and the second metal plate 12 are collectively referred to as the heat spreader 40.

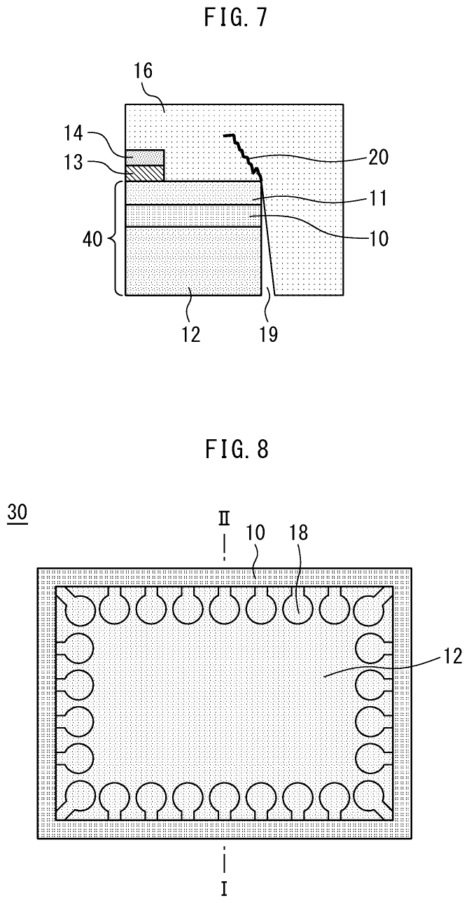

Next, the effects of the modification of the semiconductor apparatus according to the first embodiment will be described through a comparison with Comparative Example 2. FIG. 7 is an enlarged sectional view of a part of a semiconductor apparatus according to Comparative Example 2. In Comparative Example 2, the recessed groove 18 is not formed in the second metal plate 12. Since the linear expansion coefficient of the insulating mold resin 16 differs from the linear expansion coefficient of the heat spreader 40, when thermal expansion occurs due to a temperature change, the second metal plate 12 deforms, which causes peeling 19 at an interface between the heat spreader 40 and the insulating mold resin 16. The peeling 19 also causes a crack 20 in the insulating mold resin 16.

On the other hand, in the modification of the first embodiment, since the recessed groove 18 is provided on the entire periphery of the lower face of the second metal plate 12, stress can be sufficiently relieved. In addition, the inside of the recessed groove 18 is filled with the insulating mold resin 16. This reinforces the joining between the insulating mold resin 16 and the heat spreader 40. Thus, it is possible to prevent peeling of the insulating mold resin 16 caused by the difference in linear expansion coefficient between the insulating mold resin 16 and the heat spreader 40. In addition, since the occurrence of a crack in the insulating mold resin 16 caused by the peeling can be prevented, the dielectric withstand voltage is also improved. As a result, it is possible to avoid a failure of the semiconductor apparatus in a temperature humidity bias test.

### Second Embodiment

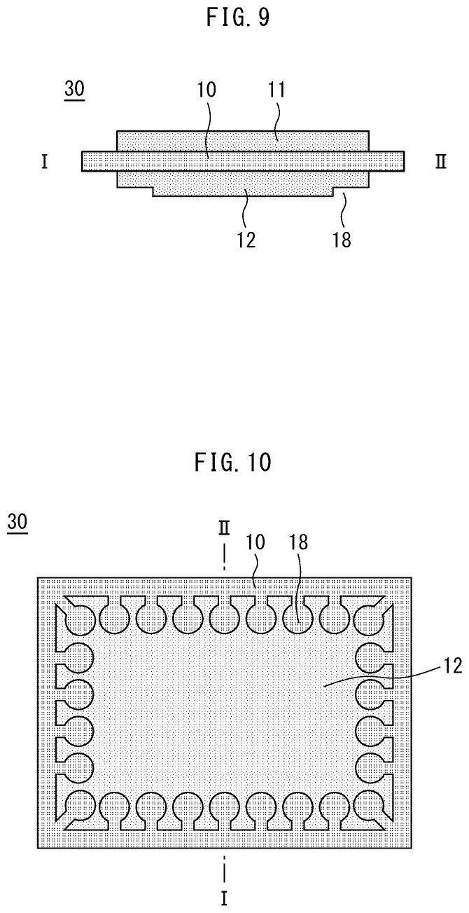

FIG. 8 is a bottom view of an insulating substrate of a semiconductor apparatus according to a second embodiment. FIG. 9 is a sectional view taken along line I-II of FIG. 8. While the recessed groove 18 having a linear shape is formed on the periphery of the second metal plate 12 in the first embodiment, the recessed groove 18 has a plurality of key-shaped grooves provided along the periphery of the lower face of the second metal plate 12 in the present embodiment. In plan view, the width of the key-shaped groove on the inner peripheral side of the lower face of the second metal plate 12 is wider than the width of the key-shaped groove on the outer peripheral side of the lower face of the second metal plate 12. The insulating mold resin 16 that fills the inside of the key-shaped grooves is resistant to tensile stress in the lateral direction due to the anchor effect. This makes it possible to prevent the insulating mold resin 16 from peeling off. The other configurations and effects are the same as those of the first embodiment.

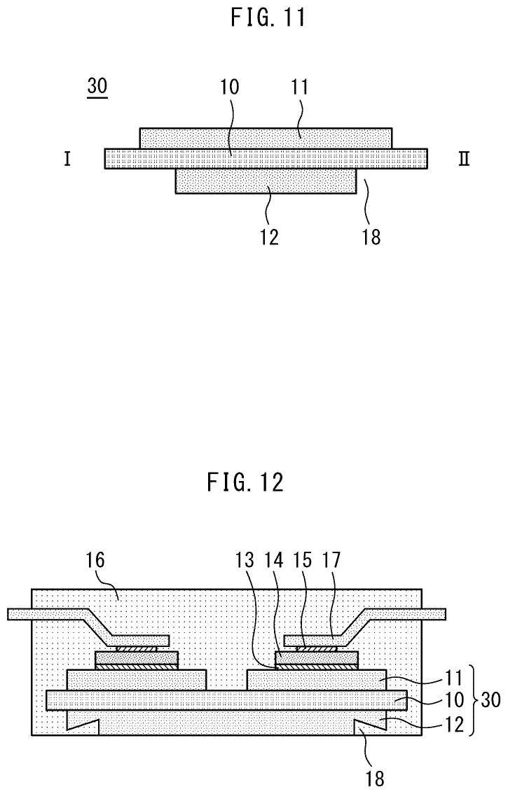

FIG. 10 is a bottom view illustrating a modification of the insulating substrate according to the second embodiment. FIG. 11 is a sectional view taken along line I-II of FIG. 10. In the modification, the depth of the key-shaped recessed groove 18 is equal to the thickness of the second metal plate 12. That is, the recessed groove 18 penetrates the second metal plate 12. Since it is easy to form such recessed grooves 18, production at a lower cost than in the case of FIGS. 8 and 9 can be achieved.

### Third Embodiment

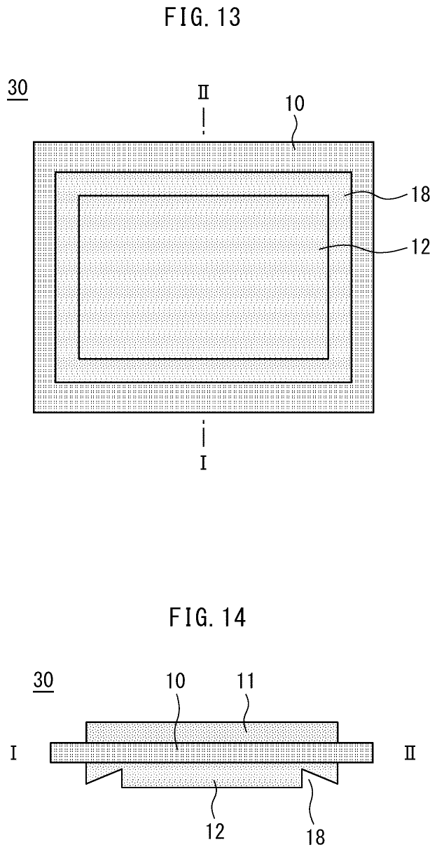

FIG. 12 is a sectional view of a semiconductor apparatus according to a third embodiment. FIG. 13 is a bottom view of an insulating substrate according to the third embodiment. FIG. 14 is a sectional view taken along line I-II of FIG. 13. The depth of the recessed groove 18 on the inner peripheral side of the lower face of the second metal plate 12 is deeper than the depth of the recessed groove 18 on the outer peripheral side of the lower face of the second metal plate 12. The recessed groove 18 has a triangular shape in sectional view. However, the insulating mold resin 16 inside the recessed groove 18 communicates with the insulating mold resin 16 outside the recessed groove 18. The insulating mold resin 16 that fills the inside of the recessed groove 18 having such a shape is resistant to tensile stress in the lateral direction due to the anchor effect. This makes it possible to prevent the insulating mold resin 16 from peeling off. The other configurations and effects are the same as those in the first embodiment.

### Fourth Embodiment

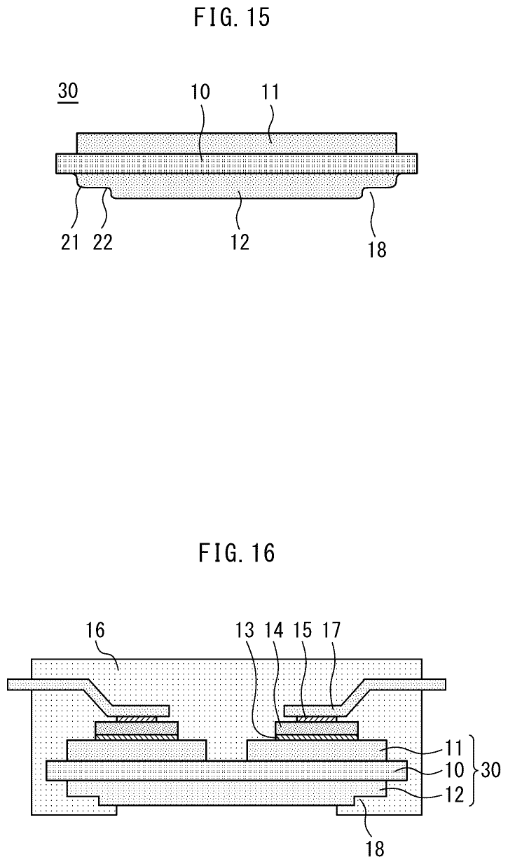

FIG. 15 is a sectional view of an insulating substrate of a semiconductor apparatus according to the fourth embodiment. A corner between a bottom face of the recessed groove 18 and a side face of the second metal plate 12 has a first R-shape 21. The curvature radius of the first R-shape 21 is 0.05 mm or more and 0.5 mm or less. This facilitates the flow of the angular filler that is contained in the insulating mold resin 16 and has an average particle diameter of 75 μm. Thus, it is possible to promote the flowability of the insulating mold resin 16 into the recessed groove 18. In addition, since local stress concentration that occurs in the insulating mold resin 16 can be relieved, it is possible to achieve even longer life.

In addition, a corner between the bottom face of the recessed groove 18 and a side face of the recessed groove 18 has a second R-shape 22. The curvature radius of the second R-shape 22 is 0.05 mm or more and 0.5 mm or less. Accordingly, only the resin contained in the insulating mold resin 16 enters the second R-shape 22. Thus, the adhesion strength is increased. In addition, the second R-shape 22 is filled with the resin in the insulating mold resin 16 at a high concentration. Thus, the adhesion area is increased, and it is possible to inhibit the insulating mold resin 16 from peeling off. In addition, by forming the second R-shape 22, it is possible to relieve the local stress of the insulating mold resin 16 and inhibit the insulating mold resin 16 from peeling off. The curvature radius of the first R-shape 21 is preferably larger than the curvature radius of the second R-shape 22. The other configurations and effects are the same as those of the first embodiment.

### Fifth Embodiment

FIG. 16 is a sectional view of a semiconductor apparatus according to a fifth embodiment. The insulating mold resin 16 not only fills the recessed groove 18, but also covers a part of the lower face of the second metal plate 12, the part being located inward of the recessed groove 18 in plan view. This increases the contact area between the insulating mold resin 16 and the second metal plate 12, and increases the joining strength between the insulating mold resin 16 and the second metal plate 12. Thus, the resistance to deformation stress is increased, and it is possible to achieve even longer life of the semiconductor apparatus. The other configurations and effects are the same as those of the first embodiment.

### Sixth Embodiment

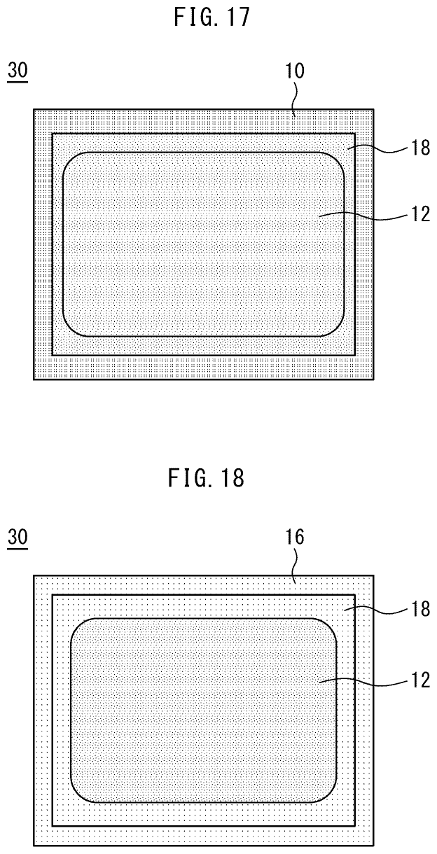

FIG. 17 is a bottom view of an insulating substrate of a semiconductor apparatus according to a sixth embodiment. FIG. 18 is a bottom view of the semiconductor apparatus according to the sixth embodiment. Each corner of a part of the lower face of the second metal plate 12, the part being exposed from the insulating mold resin 16, has an R-shape in plan view. This makes it possible to disperse local stress that occurs at the four corners of the insulating mold resin 16 that covers the second metal plate 12 and relieve the stress. In addition, when each corner of a mounting portion for a heat dissipation fin mounted on the lower face of the semiconductor apparatus has an R-shape, stress in the mounting portion can be reduced, and the life can be dramatically improved. Note that the curvature radius of the R-shape is preferably 3 mm or more and 8 mm or less. The other configurations and effects are the same as those of the first embodiment.

The configurations shown in the above embodiments are examples of the details of the present disclosure and can be combined with other known techniques. In addition, some of the configurations can be omitted or changed without departing from the gist of the present disclosure.

The semiconductor device 14 is not limited to a semiconductor device formed of silicon, but instead may be formed of a wide-bandgap semiconductor having a bandgap wider than that of silicon. The wide-bandgap semiconductor is, for example, a silicon carbide, a gallium-nitride-based material, or diamond. A semiconductor device formed of such a wide-bandgap semiconductor has a high voltage resistance and a high allowable current density, and thus can be miniaturized. The use of such a miniaturized semiconductor device enables the miniaturization and high integration of the semiconductor module in which the semiconductor device is incorporated. Further, since the semiconductor device has a high heat resistance, a radiation fin of a heatsink can be miniaturized and a water-cooled part can be air-cooled, which leads to further miniaturization of the semiconductor module. Further, since the semiconductor device has a low power loss and a high efficiency, a highly efficient semiconductor module can be achieved.

Although the preferred embodiments and the like have been described in detail above, the present disclosure is not limited to the above-described embodiments and the like, but the above-described embodiments and the like can be subjected to various modifications and replacements without departing from the scope described in the claims. Aspects of the present disclosure will be collectively described as supplementary notes.

### (Supplementary Note 1)

A semiconductor apparatus comprising:
an insulating layer;
a first metal plate provided on an upper face of the insulating layer;
a second metal plate provided on a lower face of the insulating layer;
a semiconductor device joined to the first metal plate; and
an insulating mold resin covering the insulating layer, the first metal plate, a side face of the second metal plate, and the semiconductor device,
wherein a recessed groove is provided on an entire periphery of a lower face of the second metal plate, and
an inside of the recessed groove is filled with the insulating mold resin.

### (Supplementary Note 2)

The semiconductor apparatus according to Supplementary Note 1, wherein the recessed groove has a plurality of key-shaped grooves provided along a periphery of the lower face of the second metal plate, and
a width of the key-shaped groove on an inner peripheral side of the lower face of the second metal plate is wider than a width of the key-shaped groove on an outer peripheral side of the lower face of the second metal plate in plan view.

### (Supplementary Note 3)

The semiconductor apparatus according to Supplementary Note 1, wherein a depth of the recessed groove on an inner peripheral side of the lower face of the second metal plate is deeper than a depth of the recessed groove on an outer peripheral side of the lower face of the second metal plate.

### (Supplementary Note 4)

The semiconductor apparatus according to Supplementary Note 1, wherein a corner between a bottom face of the recessed groove and a side face of the second metal plate has a first R-shape, and
a corner between the bottom face of the recessed groove and a side face of the recessed groove has a second R-shape.

### (Supplementary Note 5)

The semiconductor apparatus according to Supplementary Note 4, wherein a curvature radius of the first R-shape is 0.05 mm or more and 0.5 mm or less,
a curvature radius of the second R-shape is 0.05 mm or more and 0.5 mm or less, and
the curvature radius of the first R-shape is larger than the curvature radius of the second R-shape.

### (Supplementary Note 6)

The semiconductor apparatus according to any one of Supplementary Notes 1 to 5, wherein the insulating mold resin covers a part of the lower face of the second metal plate, the part being located inward of the recessed groove in plan view.

### (Supplementary Note 7)

The semiconductor apparatus according to Supplementary Note 1, wherein a bottom face of the recessed groove has a flat shape, and
a width of the recessed groove is 0.45 mm or more in plan view.

### (Supplementary Note 8)

The semiconductor apparatus according to any one of Supplementary Notes 1 to 7, wherein a corner of a part of the lower face of the second metal plate, the part being exposed from the insulating mold resin, has an R-shape.

### (Supplementary Note 9)

The semiconductor apparatus according to any one of Supplementary Notes 1 to 8, wherein a depth of the recessed groove is one-third a thickness of the second metal plate or more.

### (Supplementary Note 10)

The semiconductor apparatus according to any one of Supplementary Notes 1 to 9, wherein a depth of the recessed groove is less than 51% of a thickness of the second metal plate.

### (Supplementary Note 11)

The semiconductor apparatus according to any one of Supplementary Notes 1 to 10, wherein the semiconductor device is formed of a wide-bandgap semiconductor.

### REFERENCE SIGNS LIST

10 insulating layer; 11 first metal plate; 12 second metal plate; 13 first joining material; 14 semiconductor device; 15 second joining material; 16 insulating mold resin; 17 wiring member; 18 recessed groove; 19 peeling; 20 crack; 21 first R-shape; 22 second R-shape; 30 insulating substrate; 40 heat spreader

Obviously many modifications and variations of the present disclosure are possible in the light of the above teachings. It is therefore to be understood that within the scope of the appended claims the invention may be practiced otherwise than as specifically described.

The entire disclosure of Japanese Patent Application No. 2024-194145, filed on Nov. 6, 2024 including specification, claims, drawings and summary, on which the convention priority of the present application is based, is incorporated herein by reference in its entirety.

1. A semiconductor apparatus comprising:
an insulating layer;
a first metal plate provided on an upper face of the insulating layer;
a second metal plate provided on a lower face of the insulating layer;
a semiconductor device joined to the first metal plate; and
an insulating mold resin covering the insulating layer, the first metal plate, a side face of the second metal plate, and the semiconductor device,
wherein a recessed groove is provided on an entire periphery of a lower face of the second metal plate, and
an inside of the recessed groove is filled with the insulating mold resin.

2. The semiconductor apparatus according to claim 1, wherein the recessed groove has a plurality of key-shaped grooves provided along a periphery of the lower face of the second metal plate, and
a width of the key-shaped groove on an inner peripheral side of the lower face of the second metal plate is wider than a width of the key-shaped groove on an outer peripheral side of the lower face of the second metal plate in plan view.

3. The semiconductor apparatus according to claim 1, wherein a depth of the recessed groove on an inner peripheral side of the lower face of the second metal plate is deeper than a depth of the recessed groove on an outer peripheral side of the lower face of the second metal plate.

4. The semiconductor apparatus according to claim 1, wherein a corner between a bottom face of the recessed groove and a side face of the second metal plate has a first R-shape, and
a corner between the bottom face of the recessed groove and a side face of the recessed groove has a second R-shape.

5. The semiconductor apparatus according to claim 4, wherein a curvature radius of the first R-shape is 0.05 mm or more and 0.5 mm or less,
a curvature radius of the second R-shape is 0.05 mm or more and 0.5 mm or less, and
the curvature radius of the first R-shape is larger than the curvature radius of the second R-shape.

6. The semiconductor apparatus according to claim 1, wherein the insulating mold resin covers a part of the lower face of the second metal plate, the part being located inward of the recessed groove in plan view.

7. The semiconductor apparatus according to claim 1, wherein a bottom face of the recessed groove has a flat shape, and
a width of the recessed groove is 0.45 mm or more in plan view.

8. The semiconductor apparatus according to claim 1, wherein a corner of a part of the lower face of the second metal plate, the part being exposed from the insulating mold resin, has an R-shape.

9. The semiconductor apparatus according to claim 1, wherein a depth of the recessed groove is one-third a thickness of the second metal plate or more.

10. The semiconductor apparatus according to claim 1, wherein a depth of the recessed groove is less than 51% of a thickness of the second metal plate.

11. The semiconductor apparatus according to claim 1, wherein the semiconductor device is formed of a wide-bandgap semiconductor.
